(19) United States
(12) Patent Application Publication
(10) Pub. No.: US 2005/0110525 A1
(43) Pub. Date: May 26, 2005

(54) Current-mode logic circuit

(75) Inventor: Daniel Yu-Hua Chen, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/990,431

(22) Filed: Nov. 18, 2004

(30) Foreign Application Priority Data
Nov. 20, 2003 (JP) 2003-390334

(51) Int. Cl. H03K 19/094

(52) U.S. Cl. 326/115

(57) ABSTRACT

A current-mode logic (CML) circuit includes: a first field effect transistor (FET) operable based on a digital signal; a second FET operable based on an inverted digital signal; a first load circuit connected to the drain of the first FET; a second load circuit connected to the drain of the second FET; a first current limiter circuit connected between a ground line and a source node, at which the sources of the first and second FETs are connected in common; and a second current limiter circuit connected between a power supply line and a drain node, at which power line sides of the first and second load circuits are connected in common, so that the CML circuit can operate stably even with low voltage power supply.

### BACKGROUND OF THE INVENTION

1. Field of the Invention

The present invention relates to a current-mode logic circuit including a differential amplifier circuit which can operate based on a differential signal.

2. Description of the Related Art

FIG. 9 is a circuit diagram showing an example of a conventional current-mode logic (CML) circuit. Here, for easily understanding, a latch circuitry, that is a half of a D-type flip-flop circuit, is exemplified. Field effect transistors (FETs) Qa and Qb constitute a differential transistor pair, to which differential signals are supplied, where the gate of the FET Qa is supplied with a data signal D and the gate of the FET Qb is supplied with an inverted data signal DB.

A load circuit Za is connected between the drain of the FET Qa and a power supply line VD. Another load circuit Zb is connected between the drain of the FET Qb and the power supply line VD. Each source of the FETs Qa and Qb is connected in common to each other at a source node n1. An FET Qc for clock-switching is connected between the source node n1 and a ground line GND. The gate of the FET Qc is supplied with a clock signal C.

An output line La is connected to the drain of the FET Qa to transmit an inverted data signal DOB. Another output line Lb is connected to the drain of the FET Qb to transmit a data signal DO.

The gate of an FET Qd is supplied with the inverted data signal DOB via the output line La. The drain of the FET Qd is connected to the output line Lb. The gate of another FET Qe is supplied with the data signal DO via the output line Lb. The drain of the FET Qe is connected to the output line La. Each source of the FETs Qd and Qe is connected in common at a source node n2. An FET Qf for clock-switching is connected between the source node n2 and the ground line GND. The gate of the FET Qf is supplied with an inverted clock signal CB.

The operation will be explained below. In a case the clock signal C is at a high level and the inverted clock signal CB is at a low level, the FET Qc is turned on (conduction) and the FET Qf is turned off (shutoff). In another case the clock signal C is at a low level and the inverted clock signal CB is at a high level, the FET Qf is turned on and the FET Qc is turned off.

At a timing of the clock signal C rising up to a high level, if the data signal D is at a high level and the inverted data signal DB is at a low level, the inverted data signal DOB is transmitted at a high level to the output line La. At this time, the FET Qb is turned off and the data signal DO is transmitted at a high level to the output line Lb.

Next, when the clock signal C is turned to a low level, the inverted clock signal CB rises up to a high level and the FET Qf is turned on. At this time, since the data signal DO is at a high level, the FET Qe is turned on to pull down the output line La so that the inverted data signal DOB is kept at a low level. Then the FET Qd is turned off so that the data signal DO is kept at a high level.

At the next timing of the clock signal C rising up, if the data signal D is at a low level and the inverted data signal DB is at a high level, the FET Qb is turned on and the data signal DO is transmitted at a low level to the output line Lb. At this time, the FET Qa is turned off and the inverted data signal DOB is transmitted at a high level to the output line La.

At the next timing of the clock signal C falling down, the inverted clock signal is turned up to a high level and the FET Qf is turned on. At this time, since the inverted data signal DOB is at a high level, the FET Qd is turned on to pull down the output line Lb so that the data signal DO is kept at a low level. Then the FET Qe is turned off so that the inverted data signal DOB is kept at a high level.

In this manner, such a latching operation that a status of the data signal D is stored at a timing of the clock signal C rising up and kept as a data signal DO until the next timing of the clock rising up, can be effected.

FIG. 10 is a circuit diagram showing another example of a conventional current-mode logic circuit. In addition to the circuit shown in FIG. 9, each source of the FETs Qc and Qf is connected in common to each other at a source node n3, and an FET Qg is connected between the source node n3 and the ground line GND. The gate of the FET Qg is supplied with a constant bias voltage BS.

The FET Qg operates as a constant current source, which can supply a constant current depending on the bias voltage BS according to Id (drain current) vs Vg (gate voltage) characteristics. Here, adjustment of the bias voltage BS can control each amount of current passing through the FETs Qc and Qf, so that a) both voltage levels at a high level and a low level of the data signal DO and the inverted data signal DOB can be adjusted, and b) a phase error between the clock signal C and the inverted clock signal CB can be adjusted.

FIG. 11 is a circuit diagram showing an example of a bias circuit for the circuit shown in FIG. 10. Both FETs Qo and Qq constitute a current mirror circuit. An FET Qp is connected for a load of the FET Qq. The FET Qq and another FET Qr constitute another current mirror circuit. A diode-connected FET Qs is connected for a load of the FET Qr. This connection node outputs the bias voltage BS.

Incidentally, in related prior arts (e.g., Japanese Patent Unexamined Publications (kokai) JP-A-2002-118446, JP-A-9-107275 (1997), JP-A-10-270997 (1998), and IEEE Journal of Solid-State Circuits, vol. 38, No. 11, November 2003, pp. 1830-1837), disclosed are differential amplifier circuits which can operate based on a differential signal.

In the circuit shown in FIG. 9, since the drain currents of the FETs Qc and Qf for clock-switching may change due to fluctuation of the power supply voltage and the clock level, each output level of the output lines La and Lb is likely to become unstable. In the circuit shown in FIG. 10, on the other hand, providing the FET Qg serving as a constant current source can solve these problems.

However, since the additive FET Qg is provided on the ground side, a voltage loss corresponding to the on-resistance of the FET Qg occurs, thereby limiting an allowable range in fluctuation of the power supply voltage. Further, in case a lower voltage of power is supplied to the power supply line VD, crossing level of the clock signal C and the inverted signal C is lowered. Therefore, it is impossible for the FET Qg to be saturated and operate as a constant current source.

Furthermore, the bias circuit shown in FIG. 11 is sensitive to variations of IC manufacturing process, temperature, power supply voltage and the like. For the countermeasure, a bandgap type of circuit device is preferably employed. However, it is difficult to provide a bipolar device on a SOI (silicon on insulator) substrate.

### SUMMARY OF THE INVENTION

An object of the present invention is to provide a current-mode logic circuit which can operate stably even under a lower voltage of power supply.

A current-mode logic circuit according to the present invention includes:
a first field effect transistor operable based on a digital signal;
a second field effect transistor operable based on an inverted digital signal;
a first load circuit connected to the drain of the first field effect transistor;
a second load circuit connected to the drain of the second field effect transistor;
a first current limiter circuit connected between a ground line and a source node, at which each source of the first and second field effect transistors is connected in common; and
a second current limiter circuit connected between a power supply line and a drain node, at which each power line side of the first and second load circuit is connected in common.

The current-mode logic circuit may further includes:
a bias circuit for supplying each bias voltage of the first and second current limiter circuits,
wherein the bias circuit includes a current mirror circuit, a voltage divider circuit connected between the power supply line and the ground line, and a reference current controller circuit for control a reference current of the current mirror circuit based on a output voltage of the voltage divider circuit.

Additionally, a current-mode logic circuit according to the present invention includes:
a first field effect transistor operable based on a digital signal;
a second field effect transistor operable based on an inverted digital signal;
a first load circuit connected to the drain of the first field effect transistor;
a second load circuit connected to the drain of the second field effect transistor;
a third field effect transistor operable based on an inverted clock signal, being connected between a ground line and a first source node, at which each source of the first and second field effect transistors is connected in common;
a fourth field effect transistor for pulling down the drain output of the second field effect transistor when the drain voltage of the first field effect transistor is at a high level;
a fifth field effect transistor for pulling down the drain output of the first field effect transistor when the drain voltage of the second field effect transistor is at a high level;
a sixth field effect transistor operable based on a clock signal, being connected between a ground line and a second source node, at which each source of the fourth and fifth field effect transistors is connected in common; and
a current bridge circuit for supplying a bias current to the first source node, and controlling the bias current based on variation in voltage of the second source node.

In the current-mode logic circuit, the current bridge circuit may includes:
a constant current circuit being provided on the power supply line side;
a first bias transistor, the source of which is connected to the first source node, the drain of which is connected to the constant current circuit, the gate of which a bias voltage is applied to; and
a second bias transistor, the source of which is connected to the second source node, the drain of which is connected to the constant current circuit, the gate of which the bias voltage is applied to.

In the current-mode logic circuit, the constant current circuit may be composed of a diode-connected p-MOS transistor, and the first and second bias transistors may be composed of a diode-connected n-MOS transistors.

According to the present invention, the first and second field effect transistors, serving as a differential transistor pair, constitute a differential amplifier circuit together with the first current limiter circuit located on the source side. Providing the second current limiter circuit on the power line side can prevent fluctuation in voltage of the power line from affecting the differential amplifier circuit.

In addition, when the second current limiter circuit employs a field effect transistor, a voltage drop corresponding to the on-resistance occurs, thereby lowering threshold levels of an input signal and an output signal. Consequently, a level shifter circuit can be omitted at a front or subsequent stage.

### BRIEF DESCRIPTION OF THE DRAWINGS

FIG. 1 is a circuit diagram showing a first embodiment according to the present invention.

FIG. 2 is a circuit diagram showing a second embodiment according to the present invention.

FIG. 3 is a circuit diagram showing a third embodiment according to the present invention.

FIG. 4 is a circuit diagram showing a fourth embodiment according to the present invention.

FIG. 5 is a circuit diagram showing a fifth embodiment according to the present invention.

FIG. 6 is a circuit diagram showing a sixth embodiment according to the present invention.

FIG. 7 is a circuit diagram showing a seventh embodiment according to the present invention.

FIG. 8 is a circuit diagram showing an eighth embodiment according to the present invention.

FIG. 9 is a circuit diagram showing an example of a conventional current-mode logic circuit.

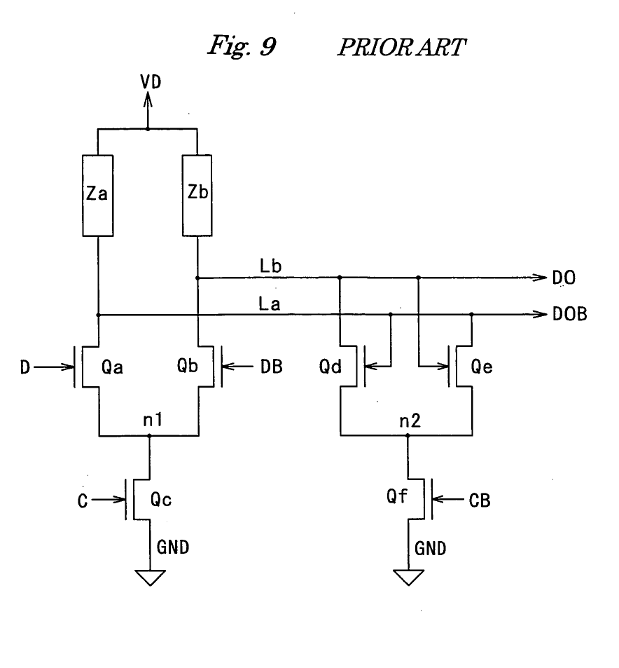

FIG. 10 is a circuit diagram showing another example of a conventional current-mode logic circuit.

FIG. 11 is a circuit diagram showing an example of a bias circuit for the circuit shown in FIG. 10.

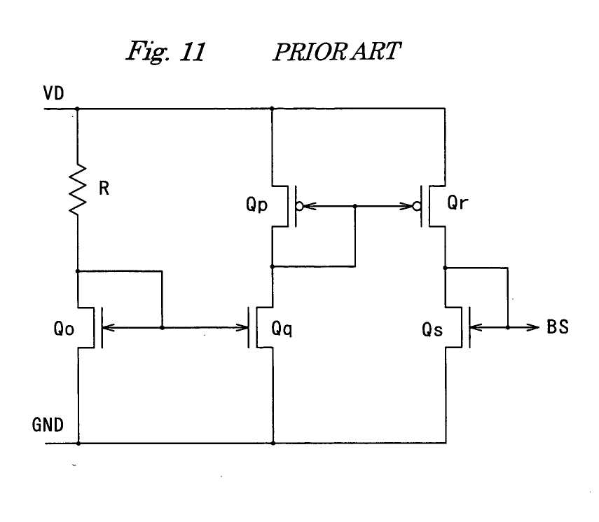

### DETAILED DESCRIPTION OF THE PREFERRED EMBODIMENTS

This application is based on an application No. 2003-390334 filed on Nov. 20, 2003 in Japan, the disclosure of which is incorporated herein by reference.

Hereinafter, preferred embodiments will be described with reference to drawings.

### Embodiment 1

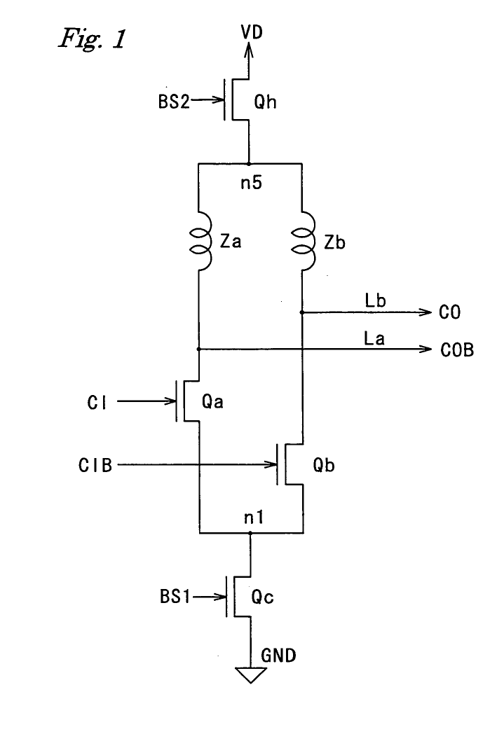

FIG. 1 is a circuit diagram showing a first embodiment according to the present invention. Here, a clock buffer circuit is exemplified for a current-mode logic (CML) circuit. Field effect transistors (FETs) Qa and Qb constitute a differential transistor pair, to which differential signals are supplied, where the gate of the FET Qa is supplied with a clock signal CI and the gate of the FET Qb is supplied with an inverted clock signal CIB.

Each source of the FETs Qa and Qb is connected in common to each other at a source node n1. Between the source node n1 and a ground line GND connected is an FET Qc for current-limiting. The gate of the FET Qc is supplied with a constant bias voltage BS1. The FETs Qa, Qb and Qc may be composed of, for example, n-MOS transistors, which can constitute a typical differential amplifier circuit.

A load circuit Za is connected to the drain of the FET Qa. Another load circuit Zb is connected to the drain of the FET Qb. Each power line side of the load circuits Za and Zb is connected in common to each other at a drain node n5. Between the drain node n5 and a power supply line VD connected is an FET Qh for current-limiting. The gate of the FET Qh is supplied with a constant bias voltage BS2.

An output line La is connected to the drain of the FET Qa to transmit an inverted clock signal COB. Another output line Lb is connected to the drain of the FET Qb to transmit an clock signal CO.

The operation will be explained below. In a case the clock signal CI is at a high level and the inverted clock signal CIB is at a low level, the FET Qa is turned on (conduction) to transmit the inverted clock signal COB at a low level to the output line La. At this time, the FET Qb is turned off (shutoff) to transmit the clock signal CO at a high level to the output line Lb.

Each of the FETs Qc and Qh operates as a constant current source, which can supply a constant current depending on each of the bias voltages BS1 and BS2, according to Id (drain current) vs Vg (gate voltage) characteristics.

In this embodiment, providing the FET Qh as a constant current source on the power line side of the differential amplifier circuit can prevent fluctuation in voltage of the power supply line VD from affecting the differential amplifier circuit.

In addition, since a voltage drop corresponding to the on-resistance of the FET Qh occurs, each threshold level of the clock signals is lowered. Consequently, a level shifter circuit can be omitted at a front or subsequent stage. Further, the load circuits Za and Zb preferably employ a inductive device, such as coil, resulting in a lower voltage drop at each of the load circuits Za and Zb.

### Embodiment 2

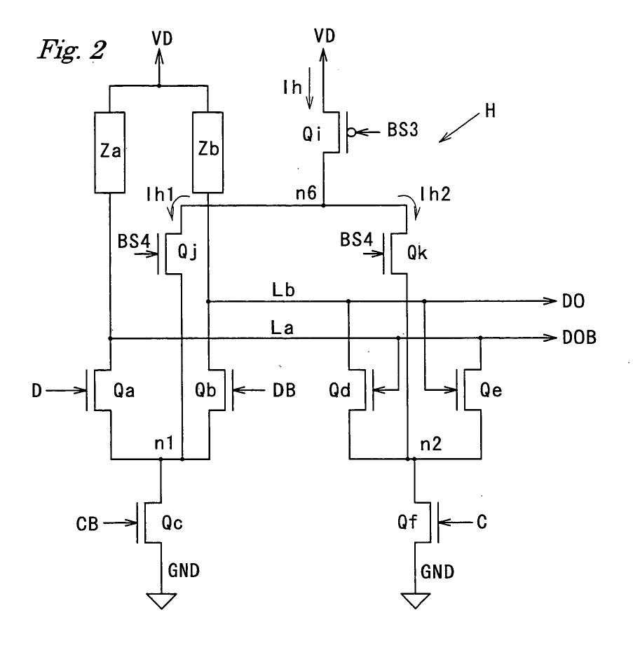

FIG. 2 is a circuit diagram showing a second embodiment according to the present invention. Here, a latch circuitry, that is a half of a D-type flip-flop circuit, is exemplified for a current-mode logic circuit. Field effect transistors (FETs) Qa and Qb constitute a differential transistor pair, to which differential signals are supplied, where the gate of the FET Qa is supplied with a data signal D and the gate of the FET Qb is supplied with an inverted data signal DB.

A load circuit Za is connected between the drain of the FET Qa and a power supply line VD. Another load circuit Zb is connected between the drain of the FET Qb and the power supply line VD. Each source of the FETs Qa and Qb is connected in common to each other at a source node n1. An FET Qc for clock-switching is connected between the source node n1 and a ground line GND. The gate of the FET Qc is supplied with an inverted clock signal CB.

An output line La is connected to the drain of the FET Qa to transmit an inverted data signal DOB. Another output line Lb is connected to the drain of the FET Qb to transmit a data signal DO.

The gate of an FET Qd is supplied with the inverted data signal DOB via the output line La. The drain of the FET Qd is connected to the output line Lb. The gate of another FET Qe is supplied with the data signal DO via the output line Lb. The drain of the FET Qe is connected to the output line La. Each source of the FETs Qd and Qe is connected in common at a source node n2. An FET Qf for clock-switching is connected between the source node n2 and the ground line GND. The gate of the FET Qf is supplied with a clock signal C. The FETs Qa to Qf may be composed of, for example, n-MOS transistors.

A current bridge circuit H includes FETs Qi, Qj and Qk. The FET Qi, which is composed of, for example, a p-MOS transistor, is connected between the power supply line VD and a node n6. The gate of the FET Qi is supplied with a constant bias voltage BS3. The FET Qi operates as a constant current source, which can supply a constant current depending on the bias voltage BS3 according to Id vs Vg characteristics.

The FET Qj, which is composed of, for example, a n-MOS transistor, is connected between the node n6 and the source node n1. The gate of the FET Qj is supplied with a constant bias voltage BS4. The FET Qk, which is composed of, for example, a n-MOS transistor, is connected between the node n6 and the source node n2. The gate of the FET Qk is supplied with the constant bias voltage BS4.

The fuction of the current bridge circuit H will be explained below. The FET Qi maintains a constant current Ih, which coincides with the sum of a current Ih1 passing through the FET Qj and a current Ih2 passing through the FET Qk (i.e. Ih=Ih1+Ih2). When the voltage of the node n1 rises up, the gate-source voltage Vgs of the FET Qj is reduced and the current Ih1 is also reduced, and then adversely the current Ih2 is increased so as to drop down the voltage of the node n2. Meanwhile, the voltage of the node n2 rises up, the gate-source voltage Vgs of the FET Qk is reduced and the current Ih2 is also reduced, and then adversely the current Ih1 is increased so as to drop down the voltage of the node n1. In this manner, the current bridge circuit H functions as to supply a bias current to each of the nodes n1 and n2 and to expand the difference between the voltages of the nodes n1 and n2.

The operation will be explained below. In a case the inverted clock signal CB is at a high level and the clock signal C is at a low level, the FET Qc is turned on (conduction) and the FET Qf is turned off (shutoff). In another case the inverted clock signal CB is at a low level and the clock signal C is at a high level, the FET Qf is turned on and the FET Qc is turned off.

At a timing of the inverted clock signal CB rising up to a high level, if the data signal D is at a high level and the inverted data signal DB is at a low level, the FET Qa is turned on and the inverted data signal DOB is transmitted at a low level to the output line La. At this time, the FET Qb is turned off and the data signal DO is transmitted at a high level to the output line Lb.

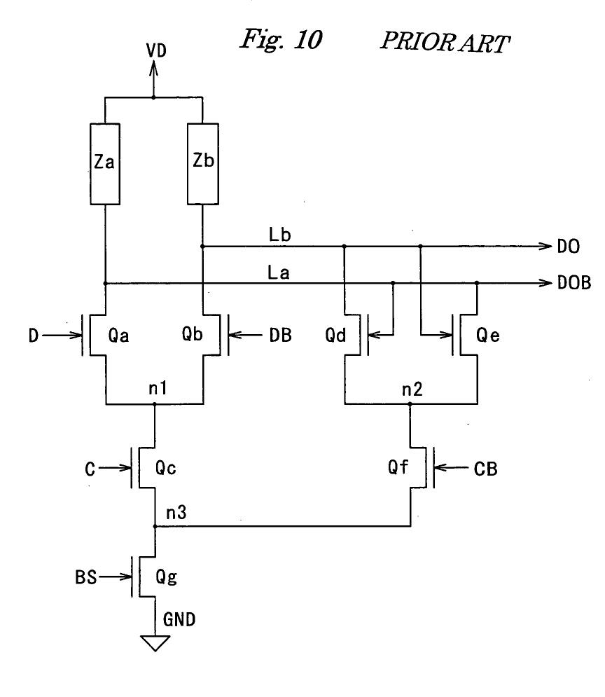

At the same time, the FET Qf is turned off and the current bridge circuit H supplies the current Ih2 to raise up the drain voltage of the FET Qf (i.e. voltage of node n2). Then, the gate-source voltage Vgs of the FET Qf is reduced and the current Ih2 is also reduced, thereby increasing the current Ih1 passing through the FET Qj. Consequently, It can prompt the drain current of any turn-on transistor out of the FETs Qa and Qb to be reduced, so that a tail current transient form on-state to off-state can be suppressed to stabilize the levels of the data signal D and the inverted signal DB before the fetching operation of the FETs Qe and Qd. Furthermore, the FET Qg used in the conventional current-mode logic circuit, as shown in FIG. 10, can be omitted.

Next, when the inverted clock signal CB is turned to a low level, the clock signal C rises up to a high level and the FET Qf is turned on. At this time, since the data signal DO is at a high level, the FET Qe is turned on to pull down the output line La so that the inverted data signal DOB is kept at a low level. Then the FET Qd is turned off so that the data signal DO is kept at a high level.

At the next timing of the inverted clock signal CB rising up, if the data signal D is at a low level and the inverted data signal DB is at a high level, the FET Qb is turned on and the data signal DO is transmitted at a low level to the output line Lb. At this time, the FET Qa is turned off and the inverted data signal DOB is transmitted at a high level to the output line La.

At the same time, as mentioned above, the current bridge circuit H can suppress a tail current when any turn-on transistor out of the FETs Qa and Qb is turned to off-state, to stabilize the levels of the data signal D and the inverted signal DB before the fetching operation of the FETs Qe and Qd.

At the next timing of the inverted clock signal CB falling down, the clock signal C is turned up to a high level and the FET Qf is turned on. At this time, since the inverted data signal DOB is at a high level, the FET Qd is turned on to pull down the output line Lb so that the data signal DO is kept at a low level. Then the FET Qe is turned off so that the inverted data signal DOB is kept at a high level.

In this manner, such a latching operation that a status of the data signal D is stored at a timing of the clock signal C rising up and kept as a data signal DO until the next timing of the clock rising up, can be effected.

### Embodiment 3

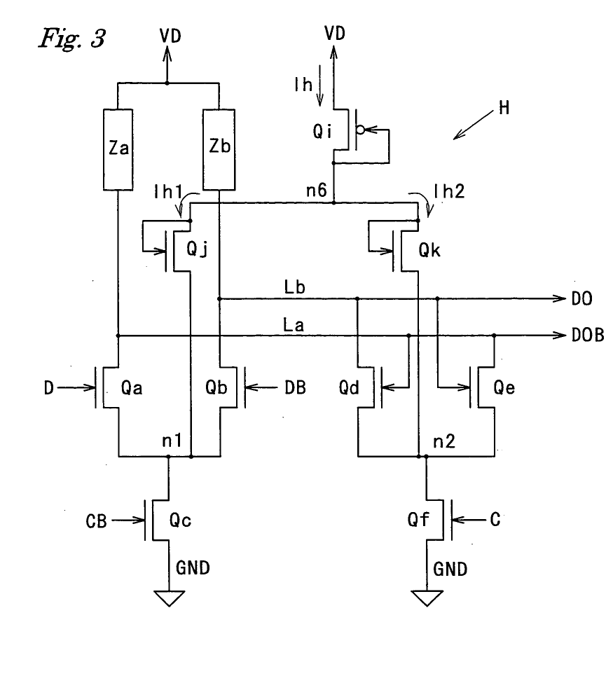

FIG. 3 is a circuit diagram showing a third embodiment according to the present invention. Here, a latch circuitry, that is a half of a D-type flip-flop circuit, is exemplified for a current-mode logic circuit. Additionally, in the current bridge circuit H as shown in FIG. 2, the FETs Qi, Qj and Qk are diode-connected so as to omit bias circuits for generating the bias voltages BS3 and BS4.

FETs Qa and Qb constitute a differential transistor pair, to which differential signals are supplied, where the gate of the FET Qa is supplied with a data signal D and the gate of the FET Qb is supplied with an inverted data signal DB.

A load circuit Za is connected between the drain of the FET Qa and a power supply line VD. Another load circuit Zb is connected between the drain of the FET Qb and the power supply line VD. Each source of the FETs Qa and Qb is connected in common to each other at a source node n1. An FET Qc for clock-switching is connected between the source node n1 and a ground line GND. The gate of the FET Qc is supplied with an inverted clock signal CB.

An output line La is connected to the drain of the FET Qa to transmit an inverted data signal DOB. Another output line Lb is connected to the drain of the FET Qb to transmit a data signal DO.

The gate of an FET Qd is supplied with the inverted data signal DOB via the output line La. The drain of the FET Qd is connected to the output line Lb. The gate of another FET Qe is supplied with the data signal DO via the output line Lb. The drain of the FET Qe is connected to the output line La. Each source of the FETs Qd and Qe is connected in common at a source node n2. An FET Qf for clock-switching is connected between the source node n2 and the ground line GND. The gate of the FET Qf is supplied with a clock signal C. The FETs Qa to Qf may be composed of, for example, n-MOS transistors.

A current bridge circuit H includes the FETs Qi, Qj and Qk. The FET Qi, which is composed of, for example, a p-MOS transistor, is connected between the power supply line VD and a node n6. Connection between the gate and the source of the FET Qi forms a diode-connection. The FET Qi operates as a constant current source, which can supply a constant current according to Id vs Vg characteristics.

The FET Qj, which is composed of, for example, a n-MOS transistor, is connected between the node n6 and the source node n1. Connection between the gate and the source of the FET Qj forms a diode-connection. The FET Qk, which is composed of, for example, a n-MOS transistor, is connected between the node n6 and the source node n2. Connection between the gate and the source of the FET Qk forms a diode-connection.

The diode-connection of each FETs Qi, Qj and Qk can constitute a simple constant current source, resulting in a simplified circuitry.

The fuction of the current bridge circuit H will be explained below. The FET Qi maintains a constant current Ih, which coincides with the sum of a current Ih1 passing through the FET Qj and a current Ih2 passing through the FET Qk (i.e. Ih=Ih1+Ih2). When the voltage of the node n1 rises up, the gate-source voltage Vgs of the FET Qj is reduced and the current Ih1 is also reduced, and then adversely the current Ih2 is increased so as to drop down the voltage of the node n2. Meanwhile, the voltage of the node n2 rises up, the gate-source voltage Vgs of the FET Qk is reduced and the current Ih2 is also reduced, and then adversely the current Ih1 is increased so as to drop down the voltage of the node n1. In this manner, the current bridge circuit H functions as to supply a bias current to each of the nodes n1 and n2 and to expand the difference between the voltages of the nodes n1 and n2.

The operation will be explained below. In a case the inverted clock signal CB is at a high level and the clock signal C is at a low level, the FET Qc is turned on (conduction) and the FET Qf is turned off (shutoff). In another case the inverted clock signal CB is at a low level and the clock signal C is at a high level, the FET Qf is turned on and the FET Qc is turned off.

At a timing of the inverted clock signal CB rising up to a high level, if the data signal D is at a high level and the inverted data signal DB is at a low level, the FET Qa is turned on and the inverted data signal DOB is transmitted at a low level to the output line La. At this time, the FET Qb is turned off and the data signal DO is transmitted at a high level to the output line Lb.

At the same time, the FET Qf is turned off and the current bridge circuit H supplies the current Ih2 to raise up the drain voltage of the FET Qf (i.e. voltage of node n2). Then, the gate-source voltage Vgs of the FET Qf is reduced and the current Ih2 is also reduced, thereby increasing the current Ih1 passing through the FET Qj. Consequently, It can prompt the drain current of any turn-on transistor out of the FETs Qa and Qb to be reduced, so that a tail current transient form on-state to off-state can be suppressed to stabilize the levels of the data signal D and the inverted signal DB before the fetching operation of the FETs Qe and Qd. Furthermore, the FET Qg used in the conventional current-mode logic circuit, as shown in FIG. 10, can be omitted.

Next, when the inverted clock signal CB is turned to a low level, the clock signal C rises up to a high level and the FET Qf is turned on. At this time, since the data signal DO is at a high level, the FET Qe is turned on to pull down the output line La so that the inverted data signal DOB is kept at a low level. Then the FET Qd is turned off so that the data signal DO is kept at a high level.

At the next timing of the inverted clock signal CB rising up, if the data signal D is at a low level and the inverted data signal DB is at a high level, the FET Qb is turned on and the data signal DO is transmitted at a low level to the output line Lb. At this time, the FET Qa is turned off and the inverted data signal DOB is transmitted at a high level to the output line La.

At the same time, as mentioned above, the current bridge circuit H can suppress a tail current when any turn-on transistor out of the FETs Qa and Qb is turned to off-state, to stabilize the levels of the data signal D and the inverted signal DB before the fetching operation of the FETs Qe and Qd.

At the next timing of the inverted clock signal CB falling down, the clock signal C is turned up to a high level and the FET Qf is turned on. At this time, since the inverted data signal DOB is at a high level, the FET Qd is turned on to pull down the output line Lb so that the data signal DO is kept at a low level. Then the FET Qe is turned off so that the inverted data signal DOB is kept at a high level.

In this manner, such a latching operation that a status of the data signal D is stored at a timing of the clock signal C rising up and kept as a data signal DO until the next timing of the clock rising up, can be effected.

### Embodiment 4

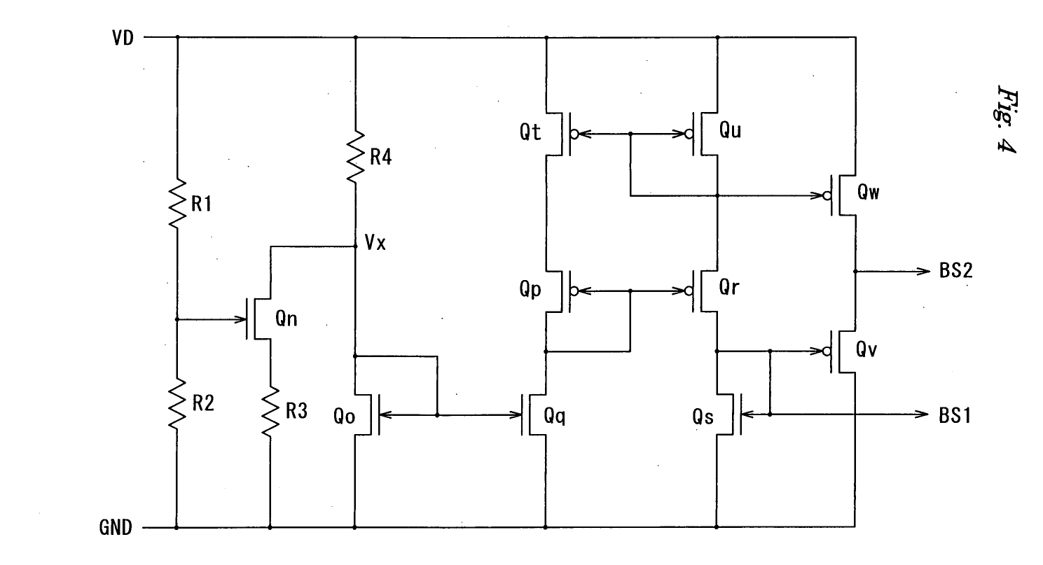

FIG. 4 is a circuit diagram showing a fourth embodiment according to the present invention. This is a circuit diagram showing an example of a bias circuit for the current-mode logic circuit as shown in FIG. 1.

Between a power supply line VD and a ground line GND provided is a voltage divider circuit, in which resistors R1 and R2 are connected in series. The output of the voltage divider circuit is connected to the gate of an FET Qn. The source of the FET Qn is connected via a resistor R3 to the ground line GND. The drain of the FET Qn is connected to the drain of an FET Qo.

Both the FET Qo and an FET Qq constitute a current mirror circuit, the sources of which are connected to the ground line GND. The drain of the FET Qo is connected via a resistor R4 to the power supply line VD. The drain of the FET Qq is connected to the power supply line VD via FETs Qp and Qt which are connected in series.

Both the FET Qp and an FET Qr constitute a current mirror circuit, and both the FET Qt and an FET Qu constitute another current mirror circuit.

The source of an FET Qs is connected to the ground line GND. The drain of the FET Qs is connected to the power supply line VD via the FETs Qr and Qu which are connected in series. Both the FET Qs and an FET Qv constitute yet another current mirror circuit. The source of the FET Qv is connected to the ground line GND. The drain of the FET Qv is connected to the power supply line VD via an FET Qw. The drain of the FET Qu is connected to the gate of the FET Qw.

The bias voltage BS1 is outputted from the source of the FET Qr. The bias voltage BS2 is outputted from the source of the FET Qw.

The FETs Qn, Qo, Qq and Qs may be composed of, for example, n-MOS transistors, and the FETs Qp, Qr, Qt, Qv and Qw may be composed of, for example, p-MOS transistors.

Now, the drain current I_{D1} of the FET Qn is calculated, where the gate voltage V_{G1} of the FET Qn, the gate-source voltage V_{GS1} of the FET Qn, the threshold voltage Vₜₕ₁ of the FET Qo, and a constant k.

$$\begin{matrix}{I}_{D1} = {k ( {V}_{GS1} - {V}_{th1} )}^{2} \\ = {k [ ( {V}_{G1} - {I}_{D1} {R}_{3} ) - {V}_{th1} ]}^{2} \\ = k [ {( {V}_{G1} - {V}_{th1} )}^{2} + {I}_{D1}^{2} {R}_{3}^{2} - 2 {I}_{D1} {R}_{3} ( {V}_{G1} - {V}_{th1} ) ]\end{matrix} \qquad [ Equation 1 ]$$

The above equation is arranged as follows:
I_{D1}−kI_{DI}²R₃²+2kI_{D1}R₃ (V_{G1}−Vₜₕ₁)=k(V_{G1}−Vₜₕ₁) [Equation 2]

In case I_{D1}<<1 and k>1, the drain current I_{D1} can be approximated as follows:

$$\begin{matrix}2 {kI}_{D1} {R}_{3} ( {V}_{G1} - {V}_{th1} ) \approx {k ( {V}_{G1} - {V}_{th1} )}^{2} \\ ∴ {I}_{D1} \approx \frac{( {V}_{G1} - {V}_{th1} )}{2 {R}_{3}}\end{matrix} \qquad [ Equation 3 ]$$

Next, we will review influence of fluctuation in voltage of the power supply line VD, where the node voltage Vₓ at the drain of the FET Qo, and the drain current I_{D2} of the FET Qo.

$$\begin{matrix}\frac{{V}_{DD} - {V}_{X}}{{R}_{4}} = {I}_{D1} + {I}_{D2} & [ Equation 4 ] \\ ∴ \frac{{V}_{DD} - {V}_{X}}{{R}_{4}} = \frac{( {V}_{G1} - {V}_{th} )}{2 {R}_{3}} + {I}_{D2} = \frac{( \frac{{R}_{2}}{{R}_{1} + {R}_{2}} {V}_{DD} - {V}_{th} )}{2 {R}_{3}} + {I}_{D2} & \\ ∴ {I}_{D2} = \frac{{V}_{DD} - {V}_{X}}{{R}_{4}} - \frac{( \frac{{R}_{2}}{{R}_{1} + {R}_{2}} {V}_{DD} - {V}_{th} )}{2 {R}_{3}} & \end{matrix}$$

Now, the sensitivity of parameter Y to parameter X is defined as the following equation to calculate the sensitivity of the drain current I_{D2} to the fluctuation in voltage VDD of the power supply line VD, provided that the node voltage Vₓ and the drain current I_{D2} must be constant.

$$\begin{matrix}{S}_{X}^{Y} = \frac{( \frac{Δ Y}{Y} )}{( \frac{Δ X}{X} )} = \frac{X}{Y} \frac{\partial Y}{\partial X} & [ Equation 5 ] \\ ∴ {S}_{{V}_{DD}}^{{I}_{D2}} = \frac{{V}_{DD}}{{I}_{D2}} \frac{\partial {I}_{D2}}{\partial {V}_{DD}} = \frac{{V}_{DD}}{{I}_{D2}} \cdot ( \frac{1}{{R}_{4}} - \frac{1}{2 {R}_{3}} \cdot \frac{{R}_{2}}{{R}_{1} + {R}_{2}} ) & \end{matrix}$$

Now, If the resistors R1 to R4 satisfy the following equation, the sensitivity of the drain current I_{D2} to the fluctuation in voltage VDD of the power supply line VD can be set as zero.

$$\frac{1}{{R}_{4}} = \frac{1}{2 {R}_{3}} \cdot \frac{{R}_{2}}{{R}_{1} + {R}_{2}} ⇒ \frac{2 {R}_{3}}{{R}_{4}} = \frac{{R}_{2}}{{R}_{1} + {R}_{2}} \qquad [ Equation 6 ]$$

When the drain current of the FET Qo is stabilized, the operating currents of the subsequent current mirror circuits are also stabilized, thereby the bias voltages BS1 and BS2 are also stabilized independently of the fluctuation in power supply voltage.

In this bias circuit, it is preferable that the FET Qn operates in a saturation region. In addition, since linearity of the FET Qn may be degraded as the drain current I_{D1} of the FET Qn increases, it is preferable that the channel length L of the FET Qn is made longer to improve the linearity of the current path including the FET Qn and the resistor R3.

### Embodiment 5

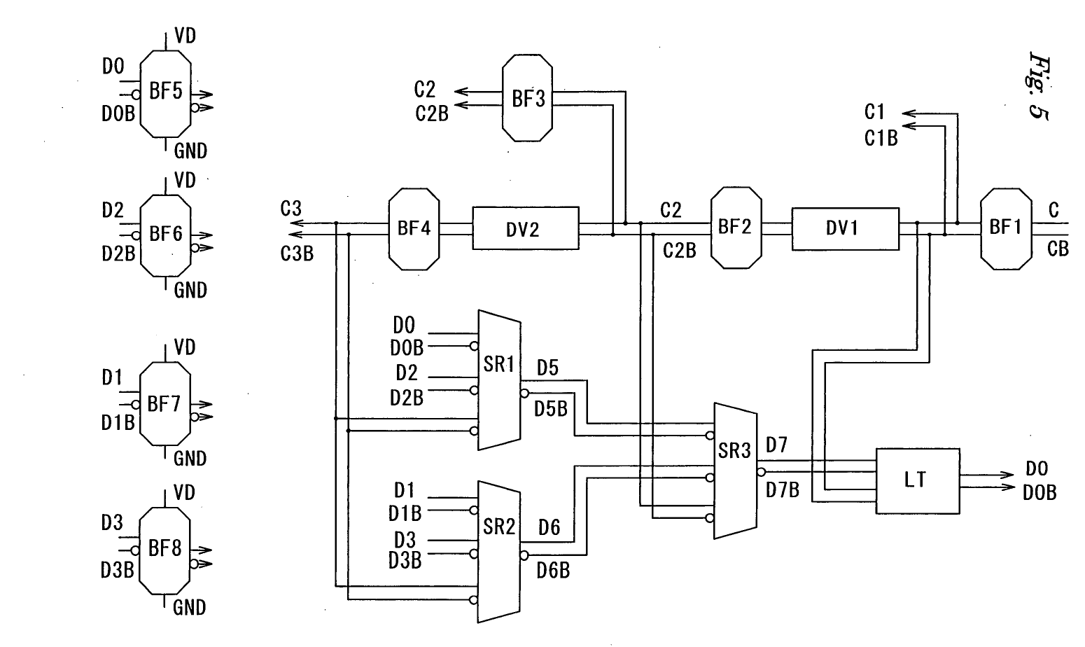

FIG. 5 is a circuit diagram showing a fifth embodiment according to the present invention. Here, a serializer circuit, which can convert a 4-bit parallel signal into a serial signal, is exemplified for a current-mode logic circuit.

The serializer circuit includes buffer circuits BF1, BF2, BF3 and BF4 for handling a clock signal and an inverted clock signal, buffer circuits BF5, BF6, BF7 and BF8 for handling a data signal and an inverted data signal, frequency-divider circuits DV1 and DV2 for dividing in half, multiplexer circuits SR1, SR2 and SR3, and a latch circuit LT.

The clock buffer circuit, as shown in FIG. 1, can be used for the buffer circuits BF1 to BF8. The D-type flip-flop circuit, as shown in either FIG. 2 or FIG. 3, can be used for the frequency-divider circuits DV1 and DV2, the multiplexer circuits SR1, SR2 and SR3, and the latch circuit LT.

The buffer circuit BF1, into which the clock signal C and the inverted clock signal CB of, for example, 10 GHz in frequency are inputted, outputs the clock signal C1 and the inverted clock signal C1B of 10 GHz to both the frequency-divider circuit DV1 and the latch-circuit LT. The frequency-divider circuit DV1 divides the clock signal C1 and the inverted clock signal C1B in half to transmit the clock signal C2 and the inverted clock signal C2B of 5 GHz via the buffer circuit BF2 to the frequency-divider circuit DV2, the multiplexer circuit SR3 and the buffer circuit BF3. The frequency-divider circuit DV2 divides the clock signal C2 and the inverted clock signal C2B in half to transmit the clock signal C3 and the inverted clock signal C3B of 2.5 GHz via the buffer circuit BF4 to the multiplexer circuits SR1 and SR2.

The multiplexer circuit SR1 includes a latch circuit which performs a latching operation at a timing of the clock signal C3 and the inverted clock signal C3B. The data signal DO and the inverted data signal DOB corresponding to the first bit of the parallel signal are inputted via the buffer circuit BF5 to the multiplexer circuit SR1. The data signal D2 and the inverted data signal D2B corresponding to the third bit of the parallel signal are inputted via the buffer circuit BF6 to the multiplexer circuit SR1. The multiplexer circuit SR1 outputs serially the data signals D0 and D2 in this sequence as a data signal D5 and the inverted data signals DOB and D2B in this sequence as an inverted data signal D5B.

The multiplexer circuit SR2 includes a latch circuit which performs a latching operation at a timing of the clock signal C3 and the inverted clock signal C3B. The data signal D1 and the inverted data signal D1B corresponding to the second bit of the parallel signal are inputted via the buffer circuit BF7 to the multiplexer circuit SR2. The data signal D3 and the inverted data signal D3B corresponding to the fourth bit of the parallel signal are inputted via the buffer circuit BF8 to the multiplexer circuit SR2. The multiplexer circuit SR2 outputs serially the data signals D1 and D3 in this sequence as a data signal D6 and the inverted data signals D1B and D3B in this sequence as an inverted data signal D6B.

The following multiplexer circuit SR3 includes a latch circuit which performs a latching operation at a timing of the clock signal C2 and the inverted clock signal C2B, to which the data signal D5 and the inverted data signal D5B are inputted and the data signal D6 and the inverted data signal D6B are inputted. The multiplexer circuit SR3 outputs serially the data signals D0, D1, D2 and D3 in this sequence as a data signal D7 and the inverted data signals DOB, D1B, D2B and D3B in this sequence as an inverted data signal D7B.

The last latch circuit LT stores the data signal D7 and the inverted data signal D7B at a timing of the clock signal C1 and the inverted clock signal C1B to output them as a data signal DO and the inverted data signal DOB.

This serializer circuit is operable under a power supply voltage of about 0.85 V, thereby reducing the power dissipation of the overall circuit. Furhter, by using the clock buffer circuit, as shown in FIG. 1, for the buffer circuits BF1 to BF8, the voltage headroom of the power supply can be widened and the internal FET can be miniaturized. In the circuit as shown in FIG. 10, for example, an FET having a channel width W of 40 μm and a channel length L of 0.1 μm is required, while in the present invention an FET having a channel width W of 16 μm and a channel length L of 0.1 μm can be used.

In addition, miniaturization of the FET leads to a smaller parasitic capacitance. Therefore, the clock signal experiences much smaller delay and the serializer circuit has more timing margin, resulting in faster operation. Further, the smaller parasitic capacitance leads to reduction of power dissipation of the overall circuit.

### Embodiment 6

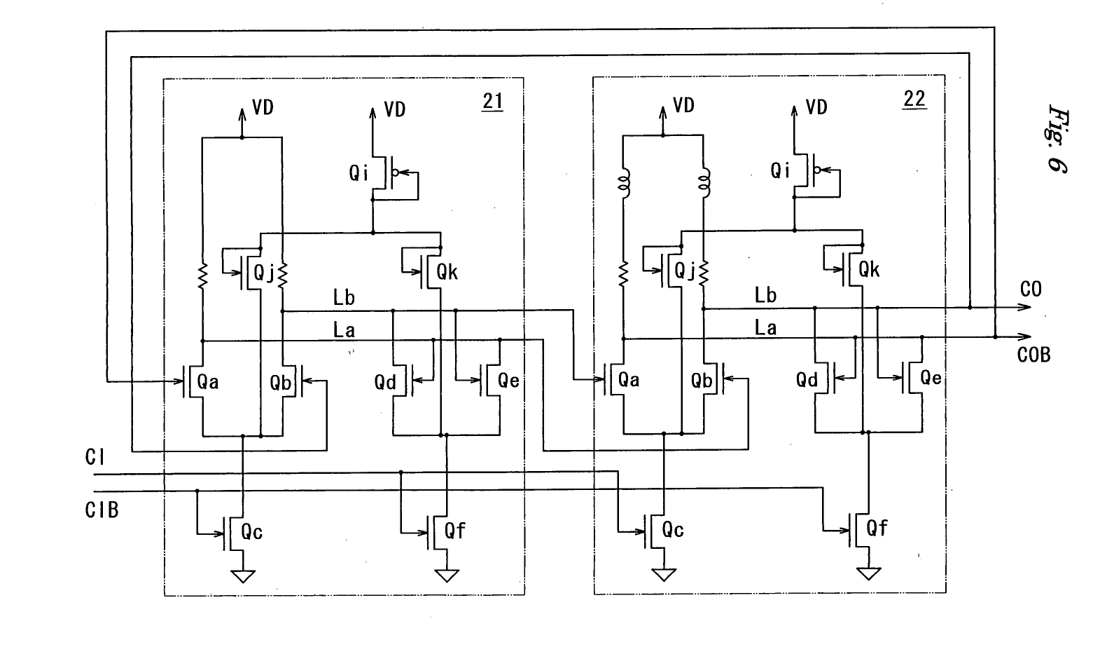

FIG. 6 is a circuit diagram showing a sixth embodiment according to the present invention. Here, a clock-divider circuit, which can divide from 8 GHz to 12 GHz, is exemplified for a current-mode logic circuit.

The clock-divider circuit includes latch circuits 21 and 22 which are connected in series, and a loop for feedback from the output of the latch circuit 22 to the input of the latch circuit 21.

The circuit, as shown in FIG. 3, can be used for the latch circuits 21 and 22. The latch circuit 21 employs resistors for load circuits of the internal differential transistor pair. The following latch circuit 22 employs inductive devices for load circuits of the internal differential transistor pair, so that the frequency bandwidth can be boosted.

### Embodiment 7

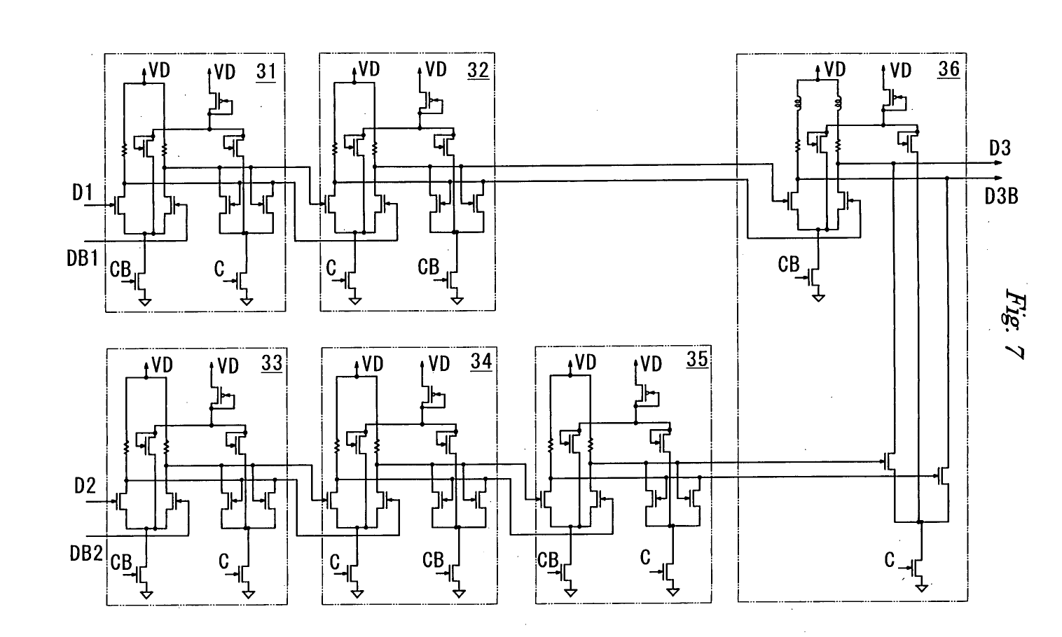

FIG. 7 is a circuit diagram showing a seventh embodiment according to the present invention. Here, a multiplexer circuit, which can multiplex 5 Gbps to 10 Gbps, is exemplified for a current-mode logic circuit.

The multiplexer circuit includes a two-stage shift register circuit in which latch circuits 31 and 32 are connected in series, a three-stage shift register circuit in which latch circuits 33, 34 and 35 are connected in series, and a selector circuit 36 for switching these outputs.

The circuit, as shown in FIG. 3, can be used for the latch circuits 31 to 35, which employ resistors for load circuits of the internal differential transistor pair. In the following selector circuit 36, each gate of the FETs Qd is and Qe is connected to each of differential output of the latch circuit 35, and employment of inductive devices for load circuits of the internal differential transistor pair facilitates the frequency bandwidth to be boosted.

### Embodiment 8

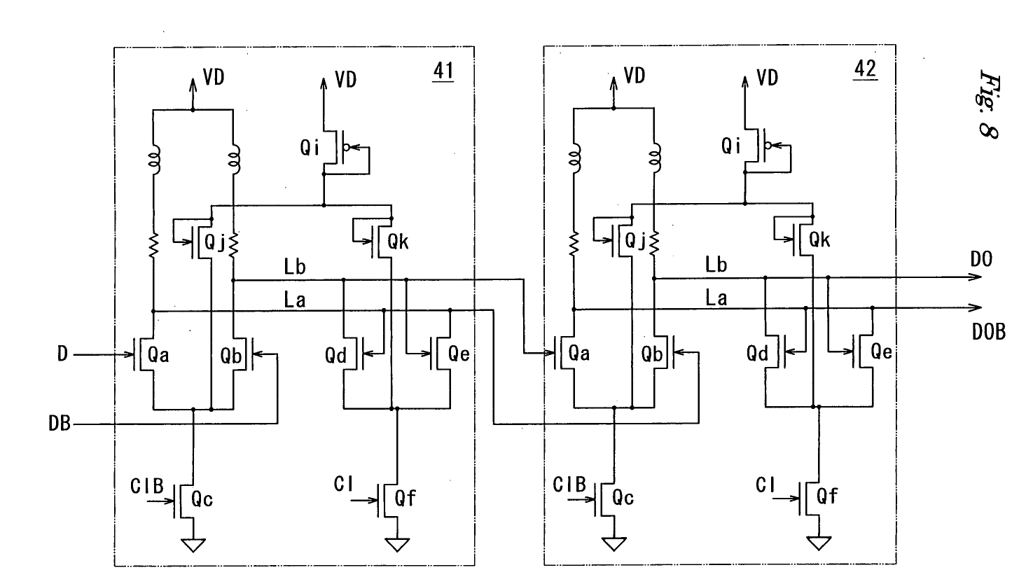

FIG. 8 is a circuit diagram showing an eighth embodiment according to the present invention. Here, a retiming circuit, which can retime at 10 Gbps, is exemplified for a current-mode logic circuit.

The retiming circuit includes latch circuits 41 and 42, which are connected in series. In a conventional retiming circuit, some clock buffer circuits are needed for canceling a delay between differential clock signals. Meanwhile, in the present invention, a smaller delay between differential clock signals leads to omission of such clock buffer circuits for delay-adjustment.

Although the present invention has been fully described in connection with the preferred embodiments thereof and the accompanying drawings, it is to be noted that various changes and modifications are apparent to those skilled in the art. Such changes and modifications are to be understood as included within the scope of the present invention as defined by the appended claims unless they depart therefrom.

1. A current-mode logic circuit comprising:
a first field effect transistor operable based on a digital signal;
a second field effect transistor operable based on an inverted digital signal;
a first load circuit connected to the drain of the first field effect transistor;
a second load circuit connected to the drain of the second field effect transistor;
a first current limiter circuit connected between a ground line and a source node, at which the sources of the first and second field effect transistors are connected in common; and
a second current limiter circuit connected between a power supply line and a drain node, at which power line sides of the first and second load circuits are connected in common.

2. The current-mode logic circuit according to claim 1, further comprising a bias circuit for supplying a bias voltage to each of the first and second current limiter circuits, wherein the bias circuit includes a current mirror circuit, a voltage divider circuit connected between a power supply line and the ground line, and a reference current controller circuit for controlling reference current of the current mirror circuit based on output voltage of the voltage divider circuit.

3. A current-mode logic circuit comprising:
a first field effect transistor operable based on a digital signal;
a second field effect transistor operable based on an inverted digital signal;
a first load circuit connected to the drain of the first field effect transistor;
a second load circuit connected to the drain of the second field effect transistor;
a third field effect transistor operable based on an inverted clock signal, connected between a ground line and a first source node, at which the sources of the first and second field effect transistors are connected in common;
a fourth field effect transistor for pulling down the output at the drain of the second field effect transistor when the drain of the first field effect transistor is at a high level voltage;
a fifth field effect transistor for pulling down the output at the drain of the first field effect transistor when the drain of the second field effect transistor is at a high level voltage;
a sixth field effect transistor operable based on a clock signal, connected between the ground line and a second source node, at which sources of the fourth and fifth field effect transistors are connected in common; and
a current bridge circuit for supplying a bias current to the first source node, and for controlling the bias current based on variation in voltage at the second source node.

4. The current-mode logic circuit according to claim 3, wherein the current bridge circuit includes:
a constant current circuit on a power supply line side;
a first bias transistor having a source connected to the first source node, a drain connected to the constant current circuit, and a gate receiving a bias voltage; and
a second bias transistor having a source connected to the second source node, a drain connected to the constant current circuit, and a gate receiving the bias voltage.

5. The current-mode logic circuit according to claim 4, wherein
the constant current circuit includes a diode-connected p-MOS transistor, and
the first and second bias transistors include diode-connected n-MOS transistors.
